(19) United States
(12) Patent Application Publication
(10) Pub. No.: US 2025/0138435 A1
(43) Pub. Date: May 1, 2025

(54) MASSIVE MEASUREMENT SAMPLING USING MULTIPLE CHUCKS AND OPTICAL COLUMNS

(71) Applicant: KLA Corporation, Milpitas, CA (US)

(72) Inventors: Jonathan Madsen, Los Altos, CA (US); Ido Dolev, Milpitas, CA (US); Daria Negri, Nesher (IL); Andrew V. Hill, Sunriver, OR (US); Izhar Agam, Milpitas, CA (US); Amnon Manassen, Haifa (IL); Oren Lahav, Milpitas, CA (US); Ohad Bachar, Timrat (IL); Yossi Simon, Qiryat Atta (IL); Yoram Uziel, Migdal Ha'emek (IL)

(73) Assignee: KLA Corporation, Milpitas, CA (US)

(21) Appl. No.: 18/383,612

(22) Filed: Oct. 25, 2023

(51) Int. Cl. G03F 7/00

(52) U.S. Cl. CPC G03F 7/70641; G03F 7/706849; G03F 7/70758

(57) ABSTRACT

A measurement system may include two or more sets of optical sub-systems to simultaneously generate measurement data on two or more samples, a coarse translation stage providing motion along a plane, two or more fine translation stages disposed on the coarse translation stage arranged in a common pattern as the two or more sets of optical sub-systems, where each of the fine translation stages provides motion along the plane and is arranged to position one of the two or more samples under one of the two or more sets of optical sub-systems. The system may further include a controller to independently direct each of the fine translation stages and the associated one of the optical sub-systems to generate measurement data for the respective samples, and generate one or more measurements for the samples based on the associated measurement data.

### TECHNICAL FIELD

The present disclosure relates generally to optical characterization, and more particularly, to metrology sampling using multiple measurement columns and multiple sample stages.

### BACKGROUND

Optical measurement systems typically include a single measurement column and a single sample on translation stages for positioning. However, the measurement throughput of such a configuration is typically limited by the translation stages. Further, efforts to provide translation stages suitable for semiconductor fabrication with relatively fast movement speeds and low settling times may be cost prohibitive and have limited impact on measurement throughput. There is therefore a need to develop systems and methods to cure the above deficiencies.

### SUMMARY

A measurement system is disclosed, in accordance with one or more illustrative embodiments. In embodiments, the system includes two or more sets of optical sub-systems configured to simultaneously generate measurement data on two or more samples. In embodiments, the system includes a coarse translation stage providing motion along a plane. In embodiments, the system includes two or more fine translation stages disposed on the coarse translation stage arranged in a common pattern as the two or more sets of optical sub-systems, where each of the two or more fine translation stages provides motion along the plane and is arranged to position one of the two or more samples under one of the two or more sets of optical sub-systems. In embodiments, the two or more fine translation stages provide at least one of a shorter travel distance than the coarse translation stage or an improved performance than the coarse translation stage according to one or more metrics. In embodiments, the system includes a controller to independently direct each of the two or more fine translation stages and the associated one of the two or more sets of optical sub-systems to generate measurement data for the respective one of the two or more samples, and generate one or more measurements for each of the two or more samples based on the associated measurement data.

A motion system is disclosed in accordance with one or more illustrative embodiments. In embodiments, the system includes two or more sets of optical sub-systems configured to simultaneously generate measurement data on two or more samples. In embodiments, the system includes a coarse translation stage providing motion along a plane. In embodiments, the system includes two or more fine translation stages disposed on the coarse translation stage and arranged in a common pattern as two or more sets of optical sub-systems, where each of the two or more fine translation stages provides motion along the plane and is arranged to position one of the two or more samples under one of the two or more sets of optical sub-systems for measurements according to a recipe. In embodiments, the two or more fine translation stages provide at least one of a shorter travel distance than the coarse translation stage or an improved resolution than the coarse translation stage.

A method is disclosed in accordance with one or more illustrative embodiments. In embodiments, the method includes positioning two or more samples for parallel measurements by two or more optical sub-systems, where the two or more samples are disposed on two or more fine translation stages coupled to a common coarse translation stage and arranged in a common pattern as two or more optical sub-systems. In embodiments, the two or more fine translation stages provide at least one of a shorter travel distance than the coarse translation stage or an improved resolution than the coarse translation stage. In embodiments, the method includes independently generating one or more measurements for the two or more samples based on measurement data from the two or more optical sub-systems.

A measurement system is disclosed, in accordance with one or more illustrative embodiments. In embodiments, the system includes two or more sets of optical sub-systems to simultaneously generate measurement data on two or more samples. In embodiments, the system includes two or more translation stages arranged in a common pattern as the two or more sets of optical sub-systems, where each of the two or more translation stages provides motion along the plane and is arranged to position one of the two or more samples under one of the two or more sets of optical sub-systems. In embodiments, the system includes a support structure providing at least mechanical support to the two or more translation stages. In embodiments, the system includes a controller to independently direct each of the two or more fine translation stages and the associated one of the two or more sets of optical sub-systems to generate measurement data for the respective one of the two or more samples, and generate one or more measurements for each of the two or more samples based on the associated measurement data.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a block diagram of a measurement system providing parallel optical measurements, in accordance with one or more embodiments of the present disclosure.

FIG. 1B is a simplified schematic of a first configuration of a measurement system, in accordance with one or more embodiments of the present disclosure.

FIG. 1C is a simplified schematic of a second configuration of a measurement system, in accordance with one or more embodiments of the present disclosure.

FIG. 1D is a simplified schematic of an optical sub-system, in accordance with one or more embodiments of the present disclosure.

FIG. 2A is a top view of a measurement system including two columns arranged side by side, each with a single optical sub-system, in accordance with one or more embodiments of the present disclosure.

FIG. 2B is a top view of a measurement system including two columns arranged side by side, each with four optical sub-systems, in accordance with one or more embodiments of the present disclosure.

FIG. 2C is a top view of a measurement system including four columns arranged in a 2D array, each with a single optical sub-system, in accordance with one or more embodiments of the present disclosure.

FIG. 3 is a simplified top view of two samples with different layouts of measurement targets that may be simultaneously characterized by the measurement system, in accordance with one or more embodiments of the present disclosure.

FIG. 4A is a top view of a measurement system including a rotatable platform in a first position, in accordance with one or more embodiments of the present disclosure.

FIG. 4B is a top view of a measurement system including a rotatable platform in a second position, in accordance with one or more embodiments of the present disclosure.

FIG. 5 is a flow diagram illustrating steps performed in a method for sample positioning, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing parallel optical measurements of samples using multiple sets of measurement columns (e.g., using multiple sets of optical sub-systems) and a unified sample positioning assembly providing independent positioning for the different samples to enable independent control of a sampling plan for each sample. For example, multiple sets of measurement columns may provide simultaneous but independent measurements on multiple samples. Further, each set of measurement columns may include a single column or multiple columns to provide one or more parallel measurements of different locations of a particular sample.

The sample positioning assembly may include various components to provide independent positioning of each sample while maintaining a unified and compact system. In some embodiments, a sample positioning assembly includes multiple independent fine translation stages to independently position samples (e.g., mounted on chucks) under the various sets of measurement columns with relatively high accuracy, where the fine translation stages are mounted to a common coarse translation stage in a pattern that matches a layout of the column sets. In this way, the coarse translation stage may provide relatively coarse positioning of all samples with respect to the column sets, while the fine translation stages may provide independent fine positioning of each sample for a measurement. In some embodiments, a measurement system includes independent translation stages for each set of measurement columns and a support structure to provide at least mechanical support for the independent translation stages. For example, such a support structure may include, but is not limited to, a monolithic granite structure, a platform, or a housing. As an illustration, a common housing may encapsulate the various translation stages and other components of the columns.

Further, the various measurement columns and the sample positioning assembly may be mounted or otherwise housed together as a single unit to provide massive sampling of multiple samples in a compact, unified system. Additionally, the various columns may share components such as, but not limited to, illumination sources and/or detectors to facilitate further compactness.

The systems and methods disclosed herein may facilitate parallel measurements on multiple samples as a technique for scaling measurement throughput. For example, the measurement throughput may scale with a number of columns and associated fine translation stages. Further, each column may implement a different measurement recipe (e.g., layouts of targets on a sample, a sampling plan, measurement parameters, or the like).

As used herein, the terms “coarse” and “fine” are used to indicate a relative degree of performance according to at least one metric. For example, a fine translation stage may have a shorter travel distance than a course translation stage. As another example, a fine translation stage may have increased performance relative to a coarse translation stage in terms of metrics including, but not limited to, accuracy, resolution, repeatability, translation speed, acceleration (e.g., speed up and/or slow-down times), or settle time.

In some embodiments, the fine translation stages further provide independent rotational, tip, and/or tilt positioning of the various samples. Independent rotational positioning may be useful for, but not limited to, providing multiple measurements of a sample at different rotational positions as a means to reduce or otherwise mitigate tool-induced-shift (TIS) or other errors.

Focus control may be provided via positioning of the samples and/or portions of an optical sub-system (e.g., optical components) along a focus direction outside of a measurement plane.

A measurement system as disclosed herein may include components to facilitate loading and/or unloading of samples. In some embodiments, samples may be independently loaded and/or unloaded by one or more sample handling systems at locations near the associated measurement column. In some applications, it may be desirable to translate samples to and from one or more dedicated loading positions. In a general sense, the various columns may be distributed in any pattern such as, but not limited to a one-dimensional (1D) or a two-dimensional (2D) array. In the case of a 2D distribution, it may be desirable to provide loading and/or unloading of samples on a single side. In some embodiments, the various fine translation stages are disposed on a rotational stage, which is in turn disposed on the coarse translation stage. In this way, samples may be rotated to one side of the system for loading and/or unloading.

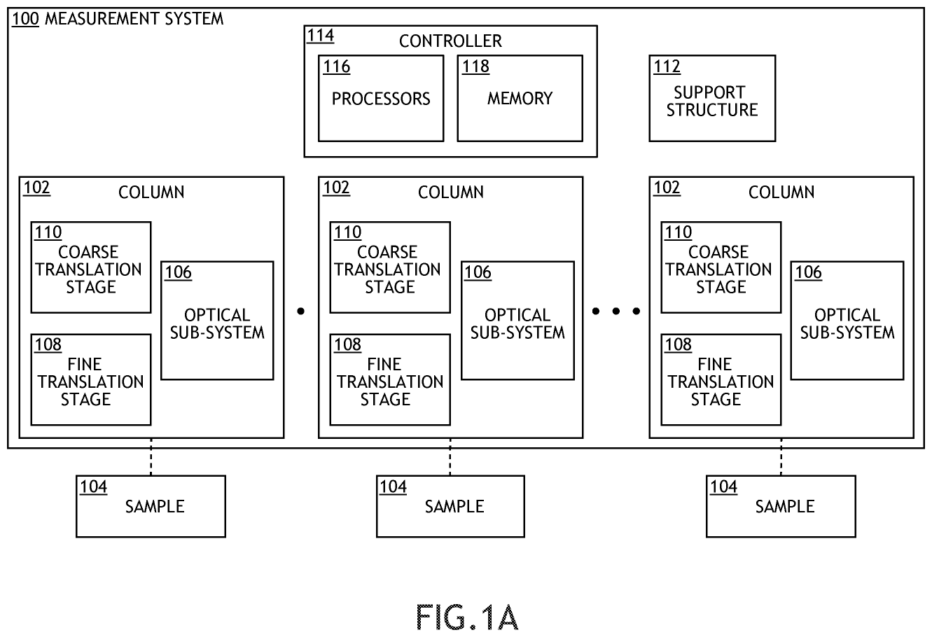

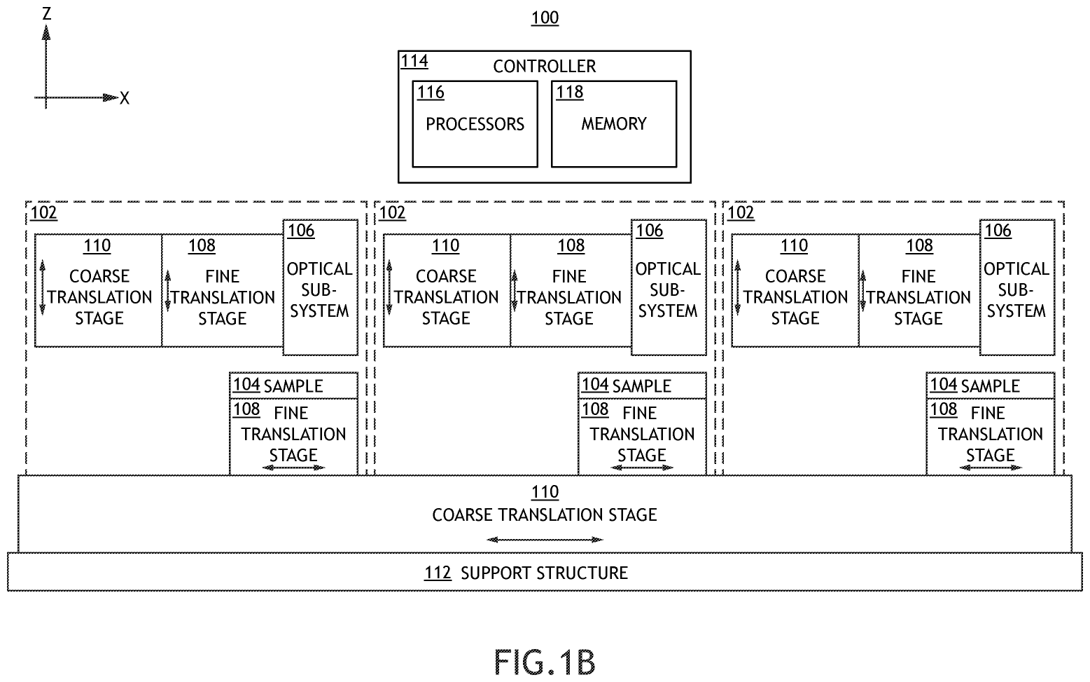

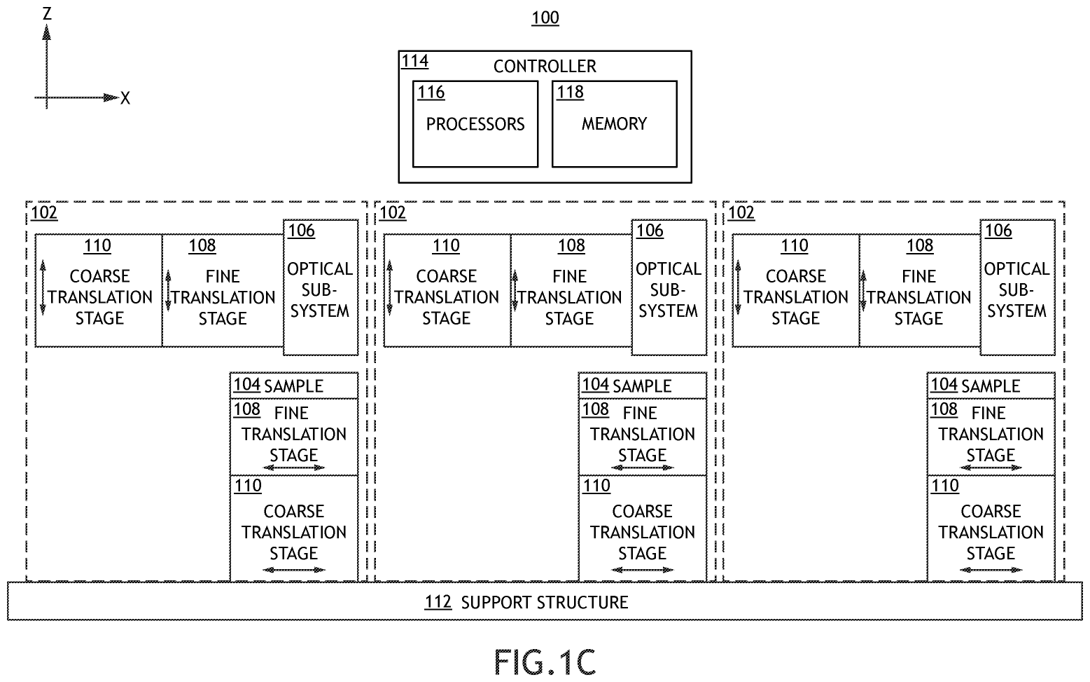

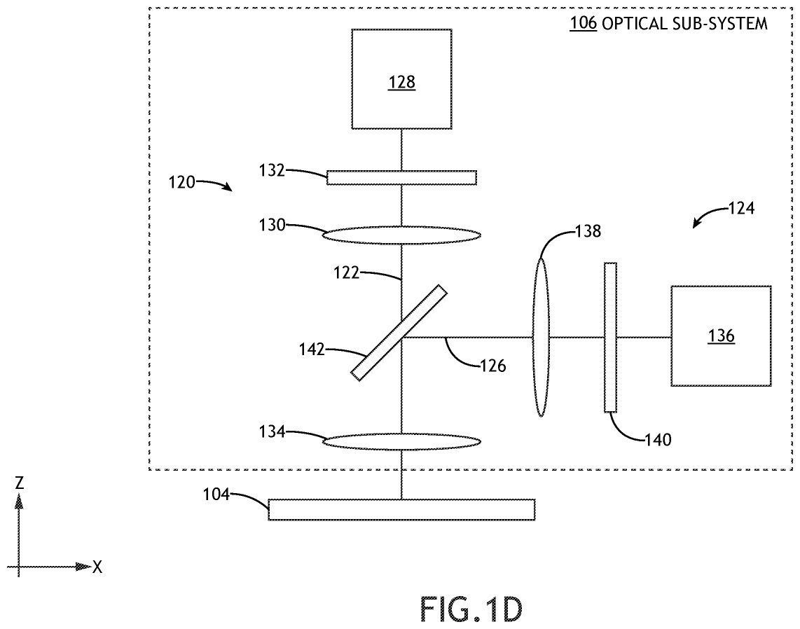

Referring now to FIGS. 1A-5, systems and methods providing parallel optical measurements are described in greater detail, in accordance with one or more embodiments of the present disclosure.

FIG. 1A is a block diagram of a measurement system 100 providing parallel optical measurements, in accordance with one or more embodiments of the present disclosure.

In some embodiments, the measurement system 100 includes two or more measurement columns 102 including components for providing independent optical measurements of different samples 104. Each column 102 may include at least one optical sub-system 106 including optical components suitable for providing measurement data of an associated sample 104. More generally, any or all of the columns 102 may include a set of one or more optical sub-systems 106. In this way, although FIG. 1A depicts a single optical sub-system 106 per column 102, this is merely an illustration and is not limiting.

In some embodiments, the measurement system 100 includes a combination of fine translation stages 108 and coarse translation stages 110 to provide independent positioning of each sample 104 under a corresponding set of optical sub-systems 106 (e.g., under a corresponding column 102) and/or focal positioning (e.g., positioning of each sample 104 and/or any of the optical sub-systems 106 along a focus direction).

The measurement system 100 may further include various structures common to all of the columns 102 to provide a unified system. In some embodiments, the measurement system 100 includes a support structure 112 configured to provide at least mechanical support to the various translation stages (e.g., the coarse translation stages 110 and the fine translation stages 108). For example, the support structure 112 may include a monolithic frame formed from any suitable material such as, but not limited to, a stone (e.g., granite or the like) or a metal (e.g., aluminum, steel, brass, or the like). Such a frame may provide mechanical support to any of the translation stages and/or the optical sub-systems 106. As another example, the support structure 112 may include a table or platform that supports components of the measurement system 100 such as, but not limited to, the optical sub-systems 106, the various translation stages, or any number of frames.

Each optical sub-system 106 may include or be configured as any type of optical measurement system. For example, any of the optical sub-systems 106 may include, or be configured as, a metrology tool suitable for providing measurements of various properties of a sample 104 such as, but not limited to, overlay, feature dimensions (e.g., critical dimensions (CDs)), composition, or thickness. As another example, any of the optical sub-systems 106 may be configured as an inspection tool suitable for identifying and/or characterizing defects on a sample 104. Further, the various optical sub-systems 106 within the measurement system 100 may be of the same type or different types. In this way, the measurement system 100 may be suitable for providing independent parallel characterization of different samples 104 using any combination of techniques.

Each optical sub-system 106 may implement a different recipe for generating measurements. A recipe may include various parameters and/or conditions that govern the acquisition of measurements across at least one sample 104. For example, a recipe may include parameters associated with a number of regions of a sample 104 to characterize (e.g., targets), placement of targets, and/or an order of measurement of such targets. Further, in applications where the targets are designed for the purposes of a measurement (e.g., metrology targets, overlay targets, or the like), the recipe may include aspects of the design of such targets including, but not limited to, the layout of features on one or more layers. As another example, a recipe may include parameters associated with the configuration of an optical sub-system 106 during a measurement. As an illustration, a recipe may include parameters associated with illumination of a target such as, but not limited to, wavelength, polarization, power, angle of incidence, spot size, or a number of illumination beams. As another illustration, a recipe may include parameters associated with collection of light from a target such as, but not limited to, wavelength, polarization, or collection angle.

In some embodiments, the sets of the optical sub-systems 106 are distributed along a measurement plane (e.g., a sample plane). Each set of optical sub-systems 106 may be distributed in any 1D or 2D distribution such as, but not limited to, a 1D or 2D array. The samples 104 may then be positioned in a common distribution as the sets of optical sub-systems 106 in the measurement plane such that each sample 104 is aligned with a corresponding set of the optical sub-systems 106 for parallel measurements. As an illustration in a case where the measurement plane is horizontal, the optical sub-systems 106 may be positioned above or below the samples 104 during a measurement. A direction orthogonal to the measurement plane (e.g., a Z direction in FIG. 1A) may be characterized as a focus direction. For example, a focus position of a sample 104 during a measurement may be characterized by an absolute position along the measurement direction and/or a relative position between the sample 104 and a corresponding optical sub-system 106 (or a component thereof such as, but not limited to, a lens) along the focus direction. Further, each set of optical sub-systems 106 may include any number of optical sub-systems 106 in any arrangement.

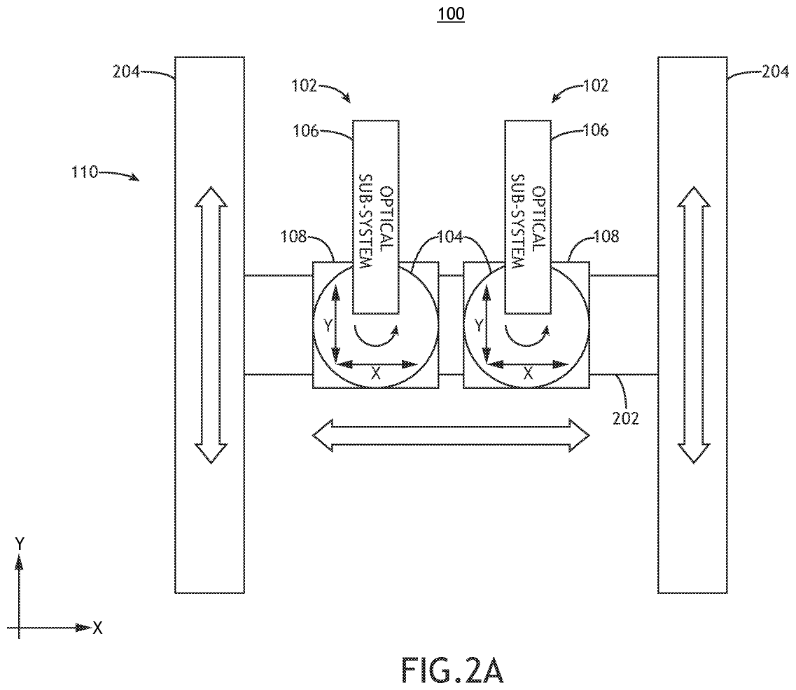

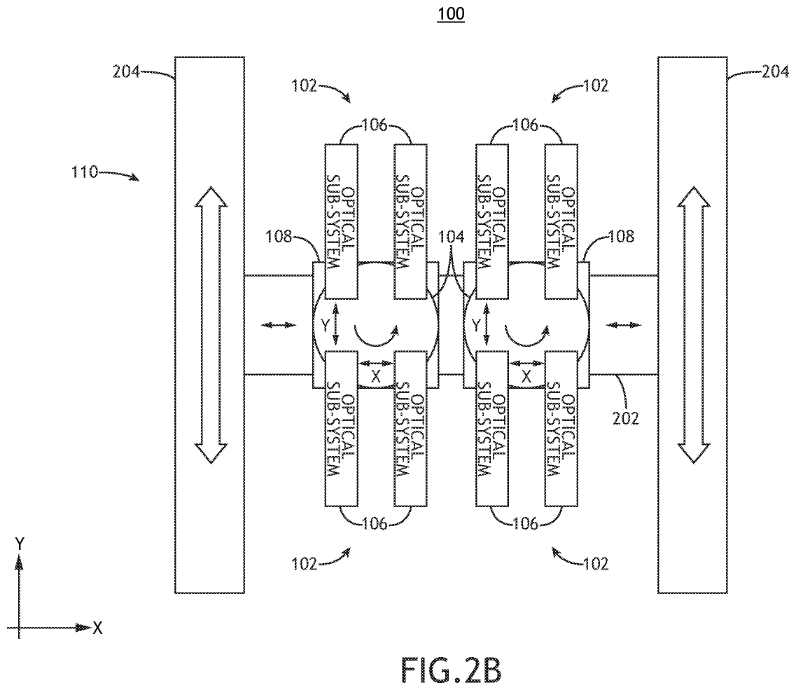

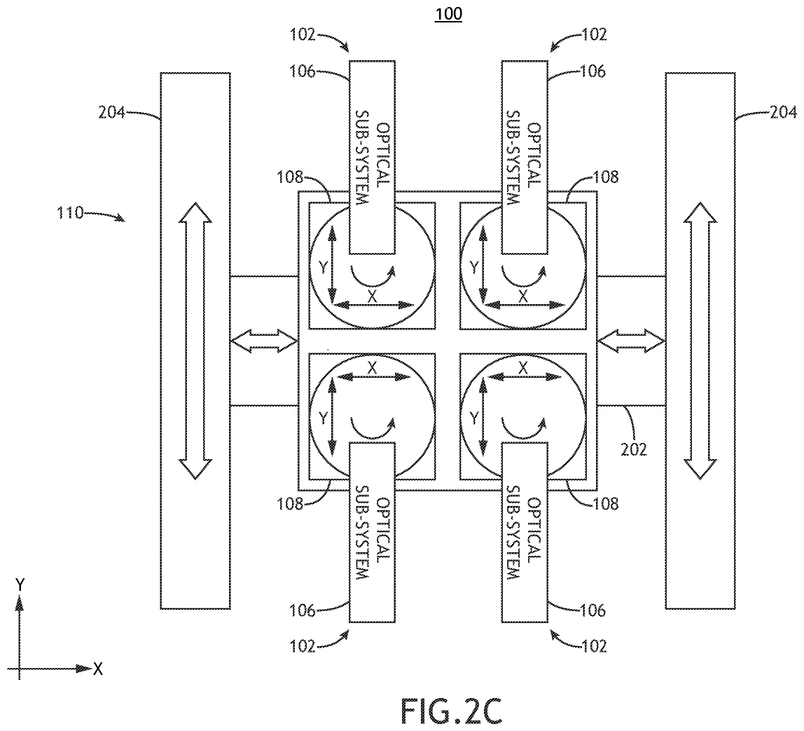

FIGS. 2A-2C depict non-limiting layouts of optical sub-systems 106, in accordance with one or more embodiments of the present disclosure. FIG. 2A is a top view of a measurement system 100 including two columns 102 arranged side by side (here, along the X direction), each with a single optical sub-system 106, in accordance with one or more embodiments of the present disclosure. FIG. 2B is a top view of a measurement system 100 including two columns 102 arranged side by side (here, along the X direction), each with four optical sub-systems 106, in accordance with one or more embodiments of the present disclosure. FIG. 2B thus illustrates a configuration in which different portions of each sample 104 may be independently characterized by different optical sub-systems 106. However, it is noted that any particular column 102 may have any number or distribution of optical sub-systems 106 such that the particular depiction in FIG. 2B is merely illustrative and not limiting on the present disclosure. FIG. 2C is a top view of a measurement system 100 including four columns 102 arranged in a 2D array, each with a single optical sub-system 106, in accordance with one or more embodiments of the present disclosure.

Referring now generally to FIGS. 1A-1C, components for positioning the samples 104 with respect to the optical sub-systems 106 for parallel measurements are now described in greater detail, in accordance with one or more embodiments of the present disclosure.

It is typically necessary to provide precise positioning of each sample 104 with respect to a corresponding set of one or more optical sub-systems 106. In a general sense, the measurement system 100 may include any combination of translation stages providing actuation along any degrees of freedom to position the samples 104 and/or components of the optical sub-systems 106. For instance, the samples 104 and/or components of the optical sub-systems 106 may be coupled to stages with linear actuators (e.g., 1D and/or two 2D actuators), rotational actuators, tip/tilt actuators, or the like. In this way, the samples 104 and/or components of the optical sub-systems 106 may be positioned with multiple degrees of freedom including a transverse position in the measurement plane, an axial position in the focus direction, or a rotational position in the measurement plane.

In some embodiments, the measurement system 100 includes a cascading arrangement of translation stages with different travel distances (e.g., ranges of motion) and/or performance parameters (e.g., accuracy, resolution, repeatability, translation speed, acceleration (e.g., speed up and/or slow-down times), or settle time) to position the samples 104 in the measurement plane (e.g., an XY plane) with respect to the various sets of optical sub-systems 106. Such a cascading arrangement of a coarse translation stage 110 and fine translation stages 108 may enable independent control of the sampling pattern for each sample 104.

For example, the measurement system 100 may include two or more fine translation stages 108 (e.g., micro stages), each securing one of the samples 104. For instance, a sample chuck (not shown) may be mounted to and/or integrated with each of the fine translation stages 108 to secure a sample 104 during a measurement. The fine translation stages 108 may then be coupled to one or more coarse translation stages 110 (e.g., macro stages) to provide additional positioning capabilities.

In some embodiments, the one or more coarse translation stages 110 provide coarse two-dimensional (2D) positioning of the samples 104 within the measurement plane (e.g., an XY plane), while the fine translation stages 108 provide independent fine positioning of each sample 104 via at least one of 2D positioning within the measurement plane, rotational positioning, or tip/tilt positioning. It is contemplated herein that rotational positioning by the fine translation stages 108 may enable accurate directional alignment of features on a sample 104 relative to illumination from an optical sub-system 106 and/or sequential measurements under rotationally-symmetric conditions to mitigate TIS or other errors.

As described previously herein, a fine translation stage 108 may have a smaller travel distance (e.g., range of motion) and/or better performance parameters (e.g., accuracy, resolution, repeatability, translation speed, acceleration (e.g., speed up and/or slow-down times), or settle time) relative to the coarse translation stage 110. Such a cascading configuration of fine translation stages 108 and a coarse translation stage 110 may provide numerous benefits for efficient positioning of samples 104. It is contemplated herein that translation stages may implement various tradeoffs between load capacity, weight, size, travel distance, travel speed, acceleration (e.g., speed up and/or slow-down times) accuracy, repeatability, cost, or the like. For instance, providing a large travel distance with high travel speed, rapid acceleration, high accuracy, and high repeatability may require substantial cost. However, a cascading arrangement of fine translation stages 108 and coarse translation stages 110 may provide an effective solution through multiple stages with different performance tradeoffs.

For example, the travel distance of a fine translation stage 108 may be approximately equal to or less than a size of a sample 104 in a relevant direction. As an illustration in the case of 300 mm semiconductor wafers, the fine translation stages 108 may have a travel distance of 300 mm or less in the measurement plane (e.g., +/−150 mm from a central position). In this configuration, the coarse translation stage 110 may provide coarse alignment of all samples 104 with respect to the optical sub-systems 106 and/or position the samples 104 for loading/unloading, while the fine translation stages 108 may provide fine alignment for each sample 104 according to a corresponding sampling plan.

Any of the fine translation stages 108 and/or the coarse translation stages 110 may be any type of stages known in the art such as, but not limited to, an air bearing stage, a mechanical bearing stage, or a magnetic levitation stage. Further, any of the fine translation stages 108 and/or the coarse translation stages 110 may have any suitable design. As an illustration, FIGS. 2A-2C depict the fine translation stages 108 as being coupled to a first-direction linear rail 202 providing motion along a first direction (e.g., the X direction), where the first-direction linear rail 202 is coupled to second-direction linear rails 204 providing motion along an orthogonal direction (e.g., the Y direction). Further, the fine translation stages 108 are depicted as providing both independent 2D positioning in the measurement plane and rotational positioning for each sample 104.

FIGS. 1B and 1C depict different configurations of a measurement system 100 with different arrangements of translation stages.

FIG. 1B is a simplified schematic of a first configuration of a measurement system 100, in accordance with one or more embodiments of the present disclosure. In FIG. 1B, the fine translation stages 108 are coupled to, or integrated with, a single coarse translation stage 110 (e.g., a macro stage). In this configuration, the coarse translation stage 110 may position all of the samples 104 near the respective optical sub-systems 106 and/or move samples 104 to and from a loading area, while the fine translation stages 108 may provide precise independent control of each sample 104. It is contemplated herein that the configuration depicted FIG. 1B may enable parallel measurements of multiple samples 104 with independent sample control within a compact, unified measurement system 100.

FIG. 1C is a simplified schematic of a second configuration of a measurement system 100, in accordance with one or more embodiments of the present disclosure. In FIG. 1C, each column 102 of the measurement system 100 includes a fine translation stage 108 and a coarse translation stage 110. Such a configuration may similarly provide parallel measurements of multiple samples 104 with independent sample control within a compact, unified measurement system 100, but may utilize a different set of tradeoffs. For instance, the configuration depicted in FIG. 1C may utilize relatively small coarse translation stages 110 rather than a single, larger coarse translation stage 110 as depicted in FIG. 1B, which may reduce the weight requirements for each coarse translation stage 110.

Further, as depicted in FIG. 1C, the translation stages for some or all of the columns 102 may be mounted to, or otherwise supported by, a common support structure 112 such as, but not limited to, a frame, a table, or a housing. For instance, a housing may encapsulate the optical sub-systems 106 as well as the various translation stages (e.g., fine translation stages 108 and/or coarse translation stages 110). The various columns 102 may also share additional components such as, but not limited to, thermal management systems or environmental systems. Further, as described in greater detail throughout, optical sub-systems 106 within the same or different columns 102 may share common components such as, but not limited to, illumination sources, detectors, controllers, or the like. In this way, such a configuration may provide advantages over alternatives including multiple independent measurement systems.

Control of a working distance between the samples 104 and the optical sub-systems 106 is now described in greater detail, in accordance with one or more embodiments of the present disclosure. In some embodiments, any of the fine translation stages 108 may provide at least 3-dimensional positioning (e.g., along X, Y, and Z directions). In this configuration, a fine translation stage 108 may adjust a position of a sample 104 relative to one or more optical sub-systems 106 in a particular column 102. In some embodiments, any of the columns 102 may include one or more translation stages configured to adjust a position of an optical sub-system 106 (or a portion thereof such as an optical head, one or more lenses, or the like) with respect to a sample 104. For the purposes of illustration, such translation stages may be referred to herein as focus translation stages. Such a configuration may provide independent control of the working distance along a focal direction for each optical sub-system 106 and may thus be particularly beneficial for, but not limited, configurations in which a column 102 has multiple optical sub-systems 106.

Further, a column 102 may include any number or type of focus translation stages for adjusting a position of an optical sub-system 106 along a focal direction (e.g., the Z direction here). For example, FIGS. 1B and 1C depict a non-limiting configuration in which each column 102 includes a fine translation stage 108 (e.g., a fine focus translation stage) and a coarse translation stage 110 (e.g., a coarse focus translation stage) to position an optical sub-system 106 along the focal direction. However, this is merely illustrative. In some embodiments, a column 102 may include a single translation stage to adjust a focus position of an optical sub-system 106 (or a portion thereof).

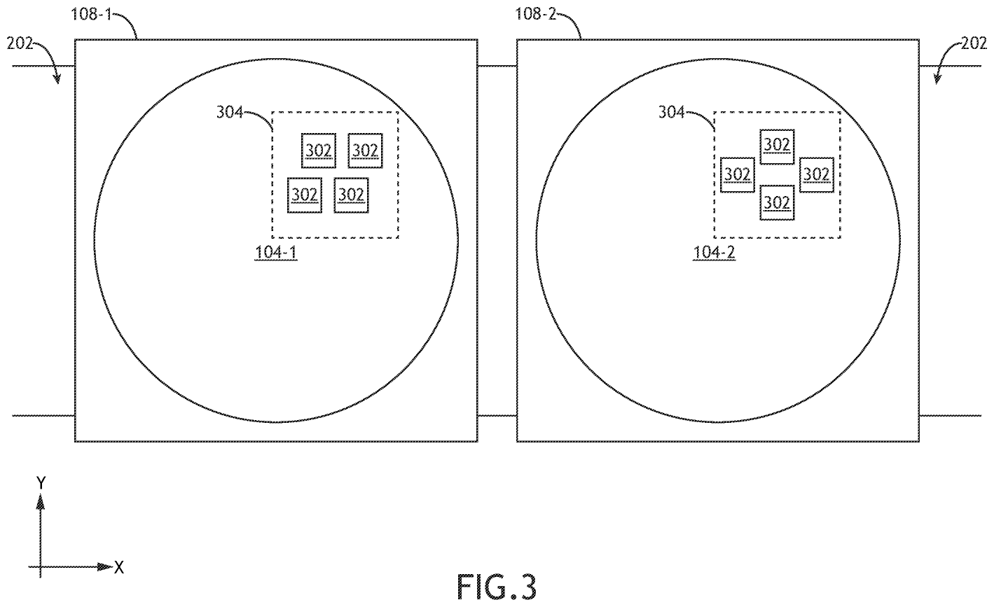

Referring now to FIG. 3, it is contemplated herein that the systems and methods disclosed herein enable parallel measurements of multiple samples 104 and/or multiple locations on each sample 104 with independently-controllable sampling plans. FIG. 3 is a simplified top view of two samples 104-1,104-2 with different layouts of measurement targets 302 that may be simultaneously characterized by the measurement system 100, in accordance with one or more embodiments of the present disclosure. In particular, the samples 104-1,104-2 are located on independent fine translation stages 108-1,108-2. Further, a portion of a coarse translation stage 110 (e.g., a first-direction linear rail 202) is shown in FIG. 3.

FIG. 3 additionally depicts different layouts of targets 302 for measurement within a sample region 304 (e.g., based on different sampling plans in different recipes). The systems and methods disclosed herein may provide parallel measurements on the two samples 104-1,104-2.

For example, if the travel distance of the fine translation stages 108-1,108-2 is equal to the sample size, a coarse translation stage 110 may position each sample 104-1,104-2 in a central location with respect to the corresponding optical sub-system 106. For example, the coarse translation stage 110 may position a central spot of each sample 104-1,104-2 in a measurement field of view of a corresponding optical sub-system 106.

The fine translation stages 108-1,108-2 may then enable measurements at any desired locations of the samples 104-1,104-2 through independent control.

As another example, if the travel distance of the fine translation stages 108-1,108-2 is shorter than the sample size, the coarse translation stage 110 may provide coarse alignment of all samples 104-1,104-2 to the respective sample region 304 such that the fine translation stages 108 may independently control the positions of the samples 104-1,104-2 within the respective sample region 304.

In either case, independent positioning by the fine translation stages 108-1, 108-2 enables parallel measurements of the samples 104-1,104-2 and thus increased measurement throughput relative to alternative techniques.

It is noted that FIG. 3 is merely illustrative and should not be interpreted and limiting. For example, FIG. 3 is not provided at scale. Further, a sample 104 may include any number or layout of targets 302.

Referring again generally to FIGS. 1A-3, it is contemplated herein that the systems and methods disclosed herein may support a wide range of sampling patterns and configurations. For example, the systems and methods disclosed herein may enable any combination of measurements based on move-and-measure (MAM) techniques or scanning techniques for any of the samples 104 or targets 302 thereon.

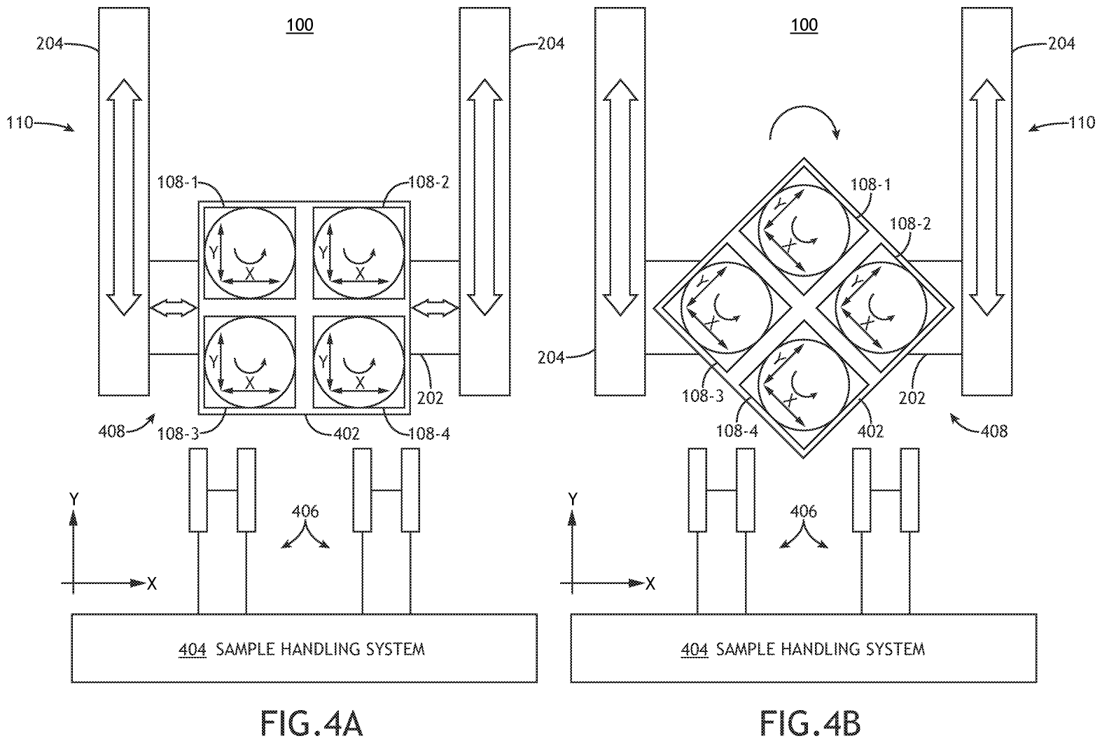

Referring now to FIGS. 4A and 4B, the loading and unloading of samples 104 is described in greater detail, in accordance with one or more embodiments of the present disclosure. FIG. 4A is a top view of a measurement system 100 including a rotatable platform 402 in a first position, in accordance with one or more embodiments of the present disclosure. FIG. 4B is a top view of a measurement system 100 including a rotatable platform 402 in a second position, in accordance with one or more embodiments of the present disclosure.

In a general sense, the measurement system 100 may be compatible with any type of sample handling system 404 in the art. In FIGS. 4A and 4B, a sample handling system 404 is depicted as having two sample handling arms 406 for loading and/or unloading samples 104, though this is merely an illustration and not limiting.

In some embodiments, a sample handling system 404 may have direct access to each of the fine translation stages 108 (e.g., sample chucks on or integrated into the fine translation stages 108). In this way, the sample handling system 404 may directly load and/or unload samples 104 onto the respective fine translation stages 108.

However, it may be desirable in some applications to facilitate loading and/or unloading in a dedicated location such as, but not limited to, a dedicated side or portion of the measurement system 100. In this case, it may be desirable to efficiently position the various fine translation stages 108 at the dedicated location.

In some embodiments, the measurement system 100 includes a rotational stage (not shown) coupled to and/or integrated with the coarse translation stage 110 to rotate the fine translation stages 108. For example, at least some of the fine translation stages 108 may be mounted to and/or integrated with a platform 402, which may be rotated by the rotational stage.

As illustrated in FIGS. 4A-4B, multiple fine translation stages 108 may be mounted to a platform 402 that may be rotated (e.g., by a rotational stage not shown) to any desired angular orientation. In this way, each of the fine translation stages 108 may be rotated to a position accessible on a selected side of the measurement system 100 for loading and/or unloading of samples 104.

In particular, FIG. 4A depicts a first orientation of the platform 402 in which fine translation stages 108-3,108-4 are positioned along a selected side 408 of the measurement system 100 to couple with the sample handling arms 406 for loading and/or unloading of samples 104. FIG. 4B depicts a second orientation of the platform 402 as it is being rotated between. FIGS. 4A-4B further depict a configuration in which the coarse translation stage 110 has positioned the fine translation stages 108 to a location near the side 408.

It is to be understood, however, that FIGS. 4A-4B are merely illustrative and not limiting. For example, the measurement system 100 may include any number of rotatable platforms 402, each securing any number of fine translation stages 108 in any distribution.

Referring now to FIGS. 1A-1D, various aspects of the optical sub-systems 106 are described in greater detail, in accordance with one or more embodiments of the present disclosure.

In some embodiments, the measurement system 100 includes a controller 114. In some embodiments, the controller 114 includes one or more processors 116 configured to execute program instructions maintained in memory 118 (e.g., a memory device). The controller 114 may be communicatively coupled with any components of the measurement system 100 to provide unidirectional communication and/or bidirectional communication. In this way, controller 114 may execute (e.g., via the one or more processors 116) program instructions causing the processors 116 to implement any of the various process steps described throughout the present disclosure such as, but not limited to, positioning (e.g., via control signals to the fine translation stages 108 and the coarse translation stage 110) the samples 104 for measurement by the optical sub-systems 106, receiving measurement data from the optical sub-systems 106 associated with the samples 104, or generating measurements for the samples 104 based on the measurement data.

The one or more processors 116 of a controller 114 may include any processing element known in the art. In this sense, the one or more processors 116 may include any microprocessor-type device configured to execute algorithms and/or instructions. In some embodiments, the one or more processors 116 may consist of a desktop computer, mainframe computer system, workstation, image computer, parallel processor, or any other computer system (e.g., networked computer) configured to execute a program configured to operate the measurement system 100, as described throughout the present disclosure. It is further recognized that the term “processor” may be broadly defined to encompass any device having one or more processing elements, which execute program instructions from a non-transitory memory 118. Further, the steps described throughout the present disclosure may be carried out by a single controller 114 or, alternatively, multiple controllers. Additionally, the controller 114 may include one or more controllers housed in a common housing or within multiple housings. In this way, any controller or combination of controllers may be separately packaged as a module suitable for integration into measurement system 100.

The memory 118 may include any storage medium known in the art suitable for storing program instructions executable by the associated one or more processors 116. For example, the memory 118 may include a non-transitory memory medium. By way of another example, the memory 118 may include, but is not limited to, a read-only memory, a random access memory, a magnetic or optical memory device (e.g., disk), a magnetic tape, a solid state drive and the like. It is further noted that memory 118 may be housed in a common controller housing with the one or more processors 116. In some embodiments, the memory 118 may be located remotely with respect to the physical location of the one or more processors 116 and controller 114. For instance, the one or more processors 116 of controller 114 may access a remote memory (e.g., server), accessible through a network (e.g., internet, intranet and the like). Therefore, the above description should not be interpreted as a limitation on the present invention but merely an illustration.

As described previously, the measurement system 100 may include any number or type of optical sub-systems 106.

FIG. 1D is a simplified schematic of an optical sub-system 106, in accordance with one or more embodiments of the present disclosure.

In some embodiments, the optical sub-system 106 includes an illumination sub-system 120 to generate illumination 122 in the form of one or more illumination beams to illuminate a sample and a collection sub-system 124 to collect light from the illuminated sample 104 (e.g., sample light 126).

In some embodiments, the illumination sub-system 120 includes an illumination source 128 configured to generate the illumination 122 in the form of at least one illumination beam. The illumination from the illumination source 128 may include one or more selected wavelengths of light including, but not limited to, ultraviolet (UV) radiation, visible radiation, or infrared (IR) radiation. The illumination source 128 may include any type of illumination source suitable for providing at least one illumination beam. In some embodiments, the illumination source 128 is a laser source. For example, the illumination source 128 may include, but is not limited to, one or more narrowband laser sources, a broadband laser source, a supercontinuum laser source, a white light laser source, or the like. In this regard, the illumination source 128 may provide an illumination beam having high coherence (e.g., high spatial coherence and/or temporal coherence). In some embodiments, the illumination source 128 includes a laser-sustained plasma (LSP) source. For example, the illumination source 128 may include, but is not limited to, a LSP lamp, a LSP bulb, or a LSP chamber suitable for containing one or more elements that, when excited by a laser source into a plasma state, may emit broadband illumination.

In some embodiments, the illumination sub-system 120 includes one or more optical components suitable for modifying and/or conditioning the one or more illumination beams as well as directing the one or more illumination beams to a sample 104. For example, the illumination sub-system 120 may include one or more illumination lenses 130. In some embodiments, the illumination sub-system 120 includes one or more illumination control optics 132 to shape or otherwise control the one or more illumination beams. For example, the illumination control optics 132 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In some embodiments, the optical sub-system 106 includes an objective lens 134 to focus the one or more illumination beams onto a sample 104 (e.g., an overlay target with overlay target elements located on two or more layers of the sample 104).

In some embodiments, the one or more illumination beams may be angularly limited on the sample 104 such that periodic structures in the sample 104 may generate discrete diffraction orders. Further, the one or more illumination beams may be spatially limited such that they may illuminate selected portions of the sample 104.

In some embodiments, the collection sub-system 124 includes one or more detectors 136, where any detector 136 may be located at any suitable location. For example, a detector 136 may be located at a field plane conjugate to a sample 104 or a pupil plane (e.g., a diffraction plane, a Fourier plane, or the like). In this way, the optical sub-system 106 may be suitable for any type of measurement. The optical sub-system 106 may include any number or type of detectors 136. In some embodiments, the optical sub-system 106 includes a multi-pixel sensor such as, but not limited to, a complementary metal-oxide-semiconductor (CMOS) device, a charge-coupled device (CCD), a photodiode array, a line sensor, or a time-delay-integration (TDI) sensor. In some embodiments, the optical sub-system 106 includes one or more single-pixel sensors such as, but not limited to, photodiodes or avalanche photodiodes. Further, one or more detectors 136 in the optical sub-system 106 may be configured to provide measurements when a sample 104 is stationary (e.g., a MaM technique) or while a sample 104 is in motion (e.g., a scanning technique).

The collection sub-system 124 may include one or more optical elements suitable for modifying and/or conditioning the sample light 126. In some embodiments, the collection sub-system 124 includes one or more collection lenses 138 (e.g., to collimate the sample light 126, to relay pupil and/or field planes, or the like), which may include, but are not required to include, the objective lens 134. In some embodiments, the collection sub-system 124 includes one or more collection control optics 140 to shape or otherwise control the sample light 126. For example, the collection control optics 140 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

Components within the optical sub-systems 106 may be arranged in any suitable manner with respect to the samples 104. For example, an optical sub-system 106 may include one or more components (e.g., one or more lenses, or the like) aligned with a sample 104 in the measurement plane (e.g., located above the sample 104) during a measurement. However, not all components need to be aligned with the sample 104. As an illustration, an optical sub-system 106 may include an optical head configured to be positioned physically near the sample 104 and additional components that may be more flexibly positioned where convenient. For instance, the optical head may include components configured to illuminate the sample 104 and/or collect light from the sample 104 during a measurement (the objective lens 134 and any number of additional components).

Further, different optical sub-systems 106 within the same or different column 102 may share one or more components. For example, two or more optical sub-systems 106 may share a common illumination source 128 and/or portions of an illumination sub-system 120. As another example, two or more optical sub-systems 106 may share a common detector 136 and/or portions of a collection sub-system 124. As an illustration, FIG. 1D depicts a beamsplitter 142 configured to allow the objective lens 134 to both direct illumination 122 to the sample 104 and collect sample light 126.

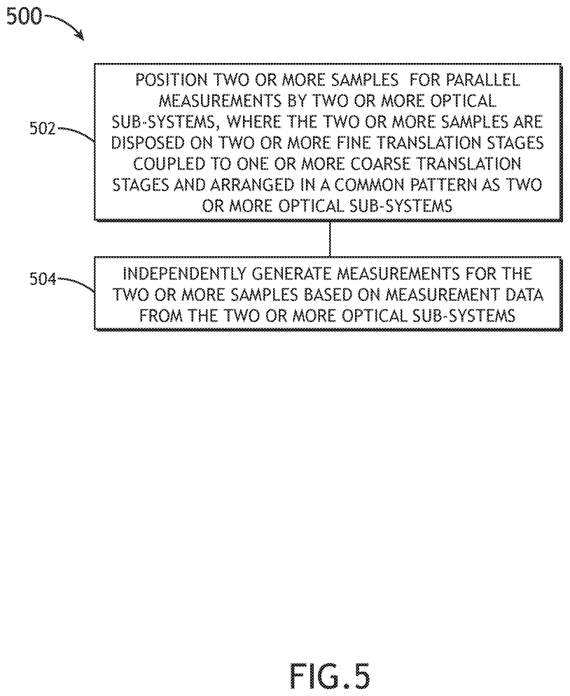

Referring now to FIG. 5, FIG. 5 is a flow diagram illustrating steps performed in a method 500 for sample positioning, in accordance with one or more embodiments of the present disclosure. The embodiments and enabling technologies described previously herein in the context of the measurement system 100 should be interpreted to extend to the method 500. For example, various components of the measurement system 100 may be configured to implement various steps of the method 500. It is further noted, however, that the method 500 is not limited to the architecture of the measurement system 100.

In some embodiments, the method 500 includes a step 502 of positioning two or more samples 104 for parallel measurements by two or more optical sub-systems 106, where the two or more samples are disposed on two or more fine translation stages 108 coupled to one or more coarse translation stages 110 and arranged in a common pattern as two or more optical sub-systems 106. For example, the two or more fine translation stages 108 may provide at least one of a shorter travel distance than the coarse translation stage 110 or an improved resolution than the one or more coarse translation stages 110.

In some embodiments, the method 500 includes a step 504 of independently generating one or more measurements for the two or more samples 104 based on measurement data from the two or more optical sub-systems 106.

Focus control when implementing the method 500 may be provided through translation stages configured to adjust positions of at least portions of the optical sub-systems 106 in a focus direction and/or the samples 104 along the focus direction.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A measurement system comprising:
two or more sets of optical sub-systems configured to simultaneously generate measurement data on two or more samples;
a coarse translation stage configured to provide motion along a plane;
two or more fine translation stages disposed on the coarse translation stage arranged in a common pattern as the two or more sets of optical sub-systems, wherein each of the two or more fine translation stages provides motion along the plane and is arranged to position one of the two or more samples under one of the two or more sets of optical sub-systems, wherein the two or more fine translation stages provide at least one of a shorter travel distance than the coarse translation stage or an improved performance than the coarse translation stage according to one or more metrics;
a controller including one or more processors configured to execute program instructions causing the one more processors to:
independently direct each of the two or more fine translation stages and the associated one of the two or more sets of optical sub-systems to generate measurement data for a respective one of the two or more samples; and
generate one or more measurements for each of the two or more samples based on the associated measurement data.

2. The measurement system of claim 1, further comprising:
two or more focus translation stages configured to provide linear motion along a focus direction orthogonal to the plane, wherein each of the two or more focus translation stages is configured to position at least a portion of one of the two or more sets of optical sub-systems along the focus direction.

3. The measurement system of claim 2, wherein the two or more focus translation stages comprise:
a fine focus translation stage and a coarse focus translation stage for each of the two or more sets of optical sub-systems.

4. The measurement system of claim 1, wherein the two or more fine translation stages further provide linear motion of the two or more samples along a focus direction orthogonal to the plane.

5. The measurement system of claim 1, wherein the two or more samples have different sampling plans, wherein independently directing each of the two or more fine translation stages and the associated one of the two or more sets of optical sub-systems to generate measurement data for the respective one of the two or more samples comprises:
independently directing each of the two or more fine translation stages and the associated one of the two or more sets of optical sub-systems to generate measurement data for the respective one of the two or more samples based on the respective one of the sampling plans.

6. The measurement system of claim 1, wherein the two or more samples have a common sampling plan, wherein independently directing each of the two or more fine translation stages and the associated one of the two or more sets of optical sub-systems to generate measurement data for the respective one of the two or more samples comprises:
independently directing each of the two or more fine translation stages and the associated one of the two or more sets of optical sub-systems to generate measurement data for the respective one of the two or more samples based on the common sampling plan.

7. The measurement system of claim 1, wherein the two or more fine translation stages further provide rotational motion in the plane.

8. The measurement system of claim 1, wherein the two or more fine translation stages are disposed on a platform, wherein the platform is rotatable by at least one of the coarse translation stage or a rotational stage disposed between the coarse translation stage and the platform.

9. The measurement system of claim 1, wherein the two or more fine translation stages have travel distances equal to or smaller than a size of the corresponding two or more samples, wherein the coarse translation stage provides a travel distance larger than the travel distances of the two or more fine translation stages.

10. The measurement system of claim 1, wherein the one or more measurements comprise:
at least one of metrology measurements or inspection measurements.

11. The measurement system of claim 1, wherein the one or more metrics comprise:
at least one of accuracy, resolution, repeatability, translation speed, acceleration, or settle time.

12. The measurement system of claim 1, wherein at least two of the two or more optical sub-systems share a common illumination source for illuminating respective samples.

13. A motion system comprising:
a coarse translation stage configured to provide motion along a plane; and
two or more fine translation stages disposed on the coarse translation stage and arranged in a common pattern as two or more sets of optical sub-systems, wherein each of the two or more fine translation stages provides motion along the plane and is arranged to position one of the two or more samples under one of the two or more sets of optical sub-systems for measurements according to a recipe, wherein the two or more fine translation stages provide at least one of a shorter travel distance than the coarse translation stage or an improved resolution than the coarse translation stage according to one or more metrics.

14. The motion system of claim 13, further comprising:
two or more focus translation stages configured to provide linear motion along a focus direction orthogonal to the plane, wherein each of the two or more focus translation stages is configured to position at least a portion of one of the two or more sets of optical sub-systems along the focus direction.

15. The motion system of claim 14, wherein the two or more focus translation stages comprise:
a fine focus translation stage and a coarse focus translation stage for each of the two or more sets of optical sub-systems.

16. The motion system of claim 13, wherein the two or more fine translation stages further provide linear motion of the two or more samples along a focus direction orthogonal to the plane.

17. The motion system of claim 13, wherein the two or more samples have different sampling plans, wherein the coarse translation stage and the two or more fine translation stages are configured to be independently directed to generate measurement data on the two or more samples based on respective sampling plans.

18. The motion system of claim 13, wherein the two or more samples have a common sampling plan, wherein the coarse translation stage and the two or more fine translation stages are configured to be simultaneously directed to generate measurement data on the two or more samples based on the common sampling plans.

19. The motion system of claim 13, wherein the two or more fine translation stages further provide rotational motion in the plane.

20. The motion system of claim 13, wherein the two or more fine translation stages are disposed on a platform, wherein the platform is rotatable by at least one of the coarse translation stage or a rotational stage disposed between the coarse translation stage and the platform.

21. The motion system of claim 13, wherein the two or more fine translation stages have travel distances equal to or smaller than a size of the corresponding two or more samples, wherein the coarse translation stage provides a travel distance larger than the travel distances of the two or more fine translation stages.

22. The motion system of claim 13, wherein the one or more metrics comprise:
at least one of accuracy, resolution, repeatability, translation speed, acceleration, or settle time.

23. A method comprising:
positioning two or more samples for parallel measurements by two or more optical sub-systems, wherein the two or more samples are disposed on two or more fine translation stages coupled to a common coarse translation stage and arranged in a common pattern as the two or more optical sub-systems, wherein the two or more fine translation stages provide at least one of a shorter travel distance than the coarse translation stage or an improved resolution than the coarse translation stage; and
independently generating one or more measurements for the two or more samples based on measurement data from the two or more optical sub-systems.

24. A measurement system comprising:
two or more sets of optical sub-systems configured to simultaneously generate measurement data on two or more samples;
two or more translation stages arranged in a common pattern as the two or more sets of optical sub-systems, wherein each of the two or more translation stages provides motion along a plane and is arranged to position one of the two or more samples under one of the two or more sets of optical sub-systems;
a support structure configured to provide at least mechanical support to the two or more translation stages; and
a controller including one or more processors configured to execute program instructions causing the one more processors to:
independently direct each of the two or more translation stages and the associated one of the two or more sets of optical sub-systems to generate measurement data for a respective one of the two or more samples; and
generate one or more measurements for each of the two or more samples based on the associated measurement data.

25. The measurement system of claim 24, wherein the support structure comprises:
a monolithic frame.

26. The measurement system of claim 25, wherein the frame is formed from at least one of granite, steel, aluminum, or brass.

27. The measurement system of claim 24, wherein the two are more translation stages are mounted to two or more frames, wherein the support structure comprises:
a platform for supporting the two or more frames.

28. The measurement system of claim 24, wherein the support structure comprises:
a housing encapsulating the two or more translation stages and the two or more sets of optical sub-systems.

29. The measurement system of claim 24, wherein the support structure further provides thermal management for the two or more translation stages.

30. The measurement system of claim 24, wherein the two or more translation stages comprises:
two or more coarse translation stages; and
two or more fine translation stages, wherein each of the two or more fine translation stages is mounted to one of the two or more coarse translation stages.

31. The measurement system of claim 24, wherein the two or more samples have different sampling plans, wherein independently directing each of the two or more translation stages and the associated one of the two or more sets of optical sub-systems to generate measurement data for the respective one of the two or more samples comprises:
independently directing each of the two or more translation stages and the associated one of the two or more sets of optical sub-systems to generate measurement data for the respective one of the two or more samples based on the respective one of the sampling plans.

32. The measurement system of claim 24, wherein the two or more samples have a common sampling plan, wherein independently directing each of the two or more translation stages and the associated one of the two or more sets of optical sub-systems to generate measurement data for the respective one of the two or more samples comprises:
independently directing each of the two or more translation stages and the associated one of the two or more sets of optical sub-systems to generate measurement data for the respective one of the two or more samples based on the common sampling plan.
